(19) United States
(12) Patent Application Publication
(10) Pub. No.: US 2025/0183610 A1
(43) Pub. Date: Jun. 5, 2025

(54) GAS LASER DEVICE AND ELECTRONIC DEVICE MANUFACTURING METHOD

(71) Applicant: Gigaphoton Inc., Tochigi (JP)

(72) Inventors: Yuki KAWASHIMA, Oyama-shi (JP); Takuya ISHII, Oyama-shi (JP); Kenshiro NAGAHAMA, Oyama-shi (JP)

(73) Assignee: Gigaphoton Inc., Tochigi (JP)

(21) Appl. No.: 19/048,135

(22) Filed: Feb. 7, 2025

Related U.S. Application Data
(63) Continuation of application No. PCT/JP2022/034778, filed on Sep. 16, 2022.

(51) Int. Cl. H01S 3/03; G03F 7/20; H01S 3/00

(52) U.S. Cl. CPC H01S 3/03; G03F 7/2006; H01S 3/0014

(57) ABSTRACT

A gas laser device includes an optical plate in an accommodating portion, a monitor module including a light entrance region and slidable on the optical plate, a positioning member on the optical plate for positioning the monitor module at a predetermined position on the optical plate, and a guide extending parallel to an optical axis of light traveling to the entrance region and guiding the monitor module toward the positioning member in the parallel direction. The monitor module includes a through-hole penetrating therethrough in the parallel direction and provided at a position deviating from the entrance region, slides on the optical plate to a predetermined region perpendicularly to the optical axis, then slides along the guide in the parallel direction toward the positioning member spaced apart from the predetermined region in the parallel direction, and is fixed in an internal space of the accommodating portion with a fixing member.

### CROSS-REFERENCE TO RELATED APPLICATIONS

The present application is a continuation application of International Application No. PCT/JP2022/034778, filed on Sep. 16, 2022, the entire contents of which are hereby incorporated by reference.

### BACKGROUND

### 1. Technical Field

The present disclosure relates to a gas laser device and an electronic device manufacturing method.

### 2. Related Art

Recently, an improvement in resolutions of semiconductor exposure devices has been desired with miniaturization and high integration of semiconductor integrated circuits. For this purpose, exposure light sources that emit light having a shorter wavelength have been developed. A KrF excimer laser device that outputs a laser beam having a wavelength of about 248 nm and an ArF excimer laser device that outputs a laser beam having a wavelength of about 193 nm, for example, are used as gas laser devices for exposure.

Spectral linewidths of spontaneous oscillation light of the KrF excimer laser device and the ArF excimer laser device are as wide as 350 pm to 400 pm. Therefore, if a projection lens is formed of a material that transmits ultraviolet light such as a KrF laser beam and an ArF laser beam, chromatic aberration may occur. As a result, resolving power may be degraded. Then, a spectral linewidth of a laser beam output from the gas laser device needs to be narrowed to the extent that chromatic aberration can be ignored. For this purpose, a line narrowing module (LNM) including a line narrowing element (etalon, grating, and the like) may be included in a laser resonator of the gas laser device to narrow the spectral linewidth. Hereinafter, the gas laser device with a narrowed spectral linewidth will be referred to as a line narrowing gas laser device.

### LIST OF DOCUMENTS

### Patent Documents

Patent Document 1: U.S. Patent Application Publication No. 2021/0103118
Patent Document 2: JP-A-2008-34480
Patent Document 3: JP-A-2005-148550

### SUMMARY

A gas laser device according to an aspect of the present disclosure may include an optical plate, a monitor module, a positioning member, and a guide. The optical plate may be accommodated in an accommodating portion. The monitor module may include an entrance region through which light enters the monitor module, and the monitor module may be slidable on the optical plate. The positioning member may be disposed on the optical plate and may position the monitor module at a predetermined position on the optical plate. The guide may extend in a direction parallel to an optical axis of the light traveling to the entrance region and may guide the monitor module toward the positioning member in the direction parallel to the optical axis of the light. The monitor module may include through-holes that penetrate through the monitor module in the direction parallel to the optical axis of the light and are provided at positions deviating from the entrance region. The monitor module may slide on the optical plate up to a predetermined region in a direction perpendicularly intersecting the optical axis of the light, may then slide along the guide in the direction parallel to the optical axis of the light toward the positioning member spaced apart from the predetermined region in the direction parallel to the optical axis of the light, and may be fixed in an internal space of the accommodating portion through screwing of fixing members that penetrate through the through-holes to the positioning member.

An electronic device manufacturing method according to an aspect of the present invention may include generating a laser beam with a gas laser device, outputting the laser beam to an exposure device, and exposing a photosensitive substrate to the laser beam within the exposure device to manufacture an electronic device. The gas laser device may include an optical plate, a monitor module, a positioning member, and a guide. The optical plate may be accommodated in an accommodating portion. The monitor module may include an entrance region through which light enters the monitor module, and the monitor module may be slidable on the optical plate. The positioning member may be disposed on the optical plate and may position the monitor module at a predetermined position on the optical plate. The guide may extend in a direction parallel to an optical axis of the light traveling to the entrance region and may guide the monitor module toward the positioning member in the direction parallel to the optical axis of the light. The monitor module may include through-holes that penetrate through the monitor module in the direction parallel to the optical axis of the light and are provided at positions deviating from the entrance region. The monitor module may slide on the optical plate up to a predetermined region in a direction perpendicularly intersecting the optical axis of the light, may then slide along the guide in the direction parallel to the optical axis of the light toward the positioning member spaced apart from the predetermined region in the direction parallel to the optical axis of the light, and may be fixed in an internal space of the accommodating portion through screwing of fixing members that penetrate through the through-holes to the positioning member.

### BRIEF DESCRIPTION OF THE DRAWINGS

Some embodiments of the present disclosure will be described below merely as examples with reference to the accompanying drawings.

FIG. 1 is a schematic diagram illustrating an overview configuration example of an entire electronic device manufacturing apparatus.

FIG. 2 is a schematic diagram illustrating an overview configuration example of an entire gas laser device of a comparative example.

FIG. 3 is a perspective view of the gas laser device of the comparative example.

FIG. 4 is a top view of a monitor module of the comparative example.

FIG. 5 is a side view of a periphery of the monitor module of the comparative example as viewed from the downstream.

FIG. 6 is a top view of an internal space of an accommodating portion of the gas laser device of the comparative example.

FIG. 7 is a top view of a periphery of a monitor module of an embodiment.

FIG. 8 is a side view of the periphery of the monitor module illustrated in FIG. 7 as viewed from the downstream.

FIG. 9 is a sectional view taken along the line A-A illustrated in FIG. 7.

FIG. 10 is a sectional view taken along the line B-B illustrated in FIG. 8.

FIG. 11 is a diagram for explaining a part of a removal operation of the monitor module in the embodiment.

FIG. 12 is a diagram for explaining another part of the removal operation of the monitor module in the embodiment.

FIG. 13 is a diagram for explaining a part of an installation operation of the monitor module in the embodiment.

FIG. 14 is a diagram for explaining another part of the installation operation of the monitor module in the embodiment.

### DESCRIPTION OF EMBODIMENTS

1. Description of Electronic Device Manufacturing Apparatus Used in Exposure Process of Electronic Device
2. Description of Gas Laser Device of Comparative Example
   2.1 Configurations
   2.2 Operations
   2.3 Removal and Installation of Monitor Module
   2.4 Problems
3. Description of Gas Laser Device of Embodiment
   3.1 Configurations
   3.2 Removal and Installation of Monitor Module
   3.3 Effects and Advantages

Hereinafter, an embodiment of the present disclosure will be described in detail with reference to the drawings. The embodiment described below illustrates some examples of the present disclosure and is not intended to limit the content of the present disclosure. Also, all configurations and operations described in the embodiment are not necessarily essential as configurations and operations of the present disclosure. Note that the same components will be denoted by the same reference signs and repeated description thereof will be omitted. In the drawings referred to below, the dimension of each member may be changed in the illustration for easy understanding.

### 1. Description of Electronic Device Manufacturing Apparatus Used in Exposure Process of Electronic Device

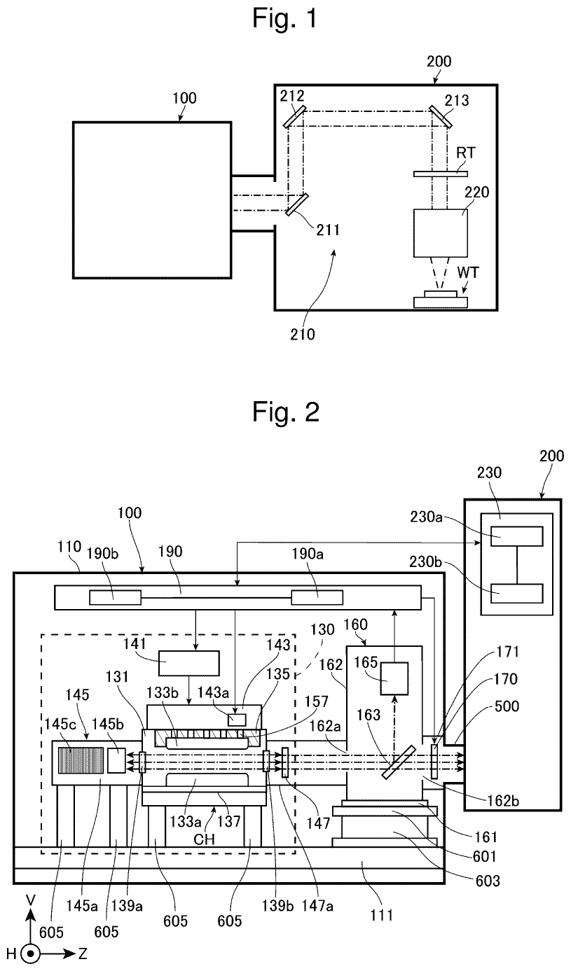

FIG. 1 is a schematic diagram illustrating an overall configuration example of an entire electronic device manufacturing apparatus used in an exposure process of an electronic device. As illustrated in FIG. 1, the manufacturing apparatus used in the exposure process includes a gas laser device 100 and an exposure device 200. The exposure device 200 includes an illumination optical system 210 including a plurality of mirrors 211, 212, and 213 and a projection optical system 220. The illumination optical system 210 illuminates a reticle pattern of a reticle which is disposed on a reticle stage RT and is not illustrated in the drawing with a laser beam that is provided from the gas laser device 100. The projection optical system 220 performs reduction projection of the laser beam transmitted through the reticle and forms an image on a workpiece which is disposed on a workpiece table WT and is not illustrated in the drawing. The workpiece is a photosensitive substrate such as a semiconductor wafer coated with a photoresist. The exposure device 200 synchronously translates the reticle stage RT and the workpiece table WT to thereby expose the workpiece to the laser beam reflecting the reticle pattern. A semiconductor device which is an electronic device can be manufactured by transferring a device pattern onto the semiconductor wafer through the exposure process as described above.

### 2. Description of Gas Laser Device of Comparative Example

### 2.1 Configurations

A gas laser device 100 of a comparative example will be described. Note that the comparative example of the present disclosure is a form recognized by the applicant as known only by the applicant and is not a publicly known example admitted by the applicant.

FIG. 2 is a schematic diagram illustrating an overall configuration example of the entire gas laser device 100 of the comparative example. The gas laser device 100 is, for example, an ArF excimer laser device using mixed gas containing argon (Ar), fluorine (F₂), and neon (Ne). The gas laser device 100 outputs a laser beam having a center wavelength of about 193 nm. Note that the gas laser device 100 may be a gas laser device other than the ArF excimer laser device and may be, for example, a KrF excimer laser device using mixed gas containing krypton (Kr), F₂, and Ne. In this case, the gas laser device 100 outputs a laser beam having a center wavelength of about 248 nm. The mixed gas containing Ar, F₂, and Ne which are laser media and the mixed gas containing Kr, F₂, and Ne which are laser media may be referred to as laser gas.

The gas laser device 100 includes, as main configurations, an accommodating portion 110, a laser oscillator 130 disposed in an internal space of the accommodating portion 110, a monitor module 160, a shutter 170, and a laser processor 190.

The accommodating portion 110 includes a plurality of laser frames 111 and forms a box-shaped framework by coupling the laser frames 111. Each of a left side surface, a right side surface, a front surface, a rear surface, an upper surface, and a lower surface of the accommodating portion 110 is provided with an opening. These openings are each covered by a cover such as a panel attached to the laser frames 111, and an internal space of the accommodating portion 110 is thus a sealed space. The openings each have a quadrangular shape, the laser frames 111 are quadrangular prism members, and examples of a material of the laser frames 111 include metal such as stainless steel and aluminum. Note that the shapes of the openings and the laser frames 111 are not particularly limited.

The laser oscillator 130 includes a chamber 131, a charger 141, a pulse power module 143, a line narrowing module 145, and an output coupling mirror 147. FIG. 2 illustrates an internal configuration of the chamber 131 as viewed from a direction substantially perpendicular to a traveling direction of a laser beam.

Examples of a material of the chamber 131 may include metal such as aluminum plated with nickel and stainless steel plated with nickel. The chamber 131 includes an internal space in which the laser gas is sealed and light is generated by excitation of the laser media in the laser gas. The light travels toward windows 139a and 139b, which will be described later. The laser gas is supplied from a laser gas supply source, which is not illustrated, to the internal space of the chamber 131 through a pipe, which is not illustrated. In addition, the laser gas in the chamber 131 is subjected to a process of removing F₂ gas with a halogen filter or the like and is then discharged to the outside of the accommodating portion 110 through a pipe, which is not illustrated, by an exhaust pump, which is not illustrated.

In the internal space of the chamber 131, an electrode 133a and an electrode 133b are spaced apart from each other and face each other, and the longitudinal direction of the electrodes 133a and 133b is along the traveling direction of the laser beam. The following description may be given on the assumption that the longitudinal direction of the electrodes 133a and 133b is a Z direction, a direction that is an alignment direction of the electrodes 133a and 133b and a separation direction in which the electrodes 133a and 133b are spaced apart from each other and that perpendicularly intersects the Z direction is a V direction, and a direction that perpendicularly intersects the V direction and the Z direction is an H direction. The electrodes 133a and 133b are discharge electrodes to excite the laser media through glow discharge. In this embodiment, the electrode 133a is an anode, and the electrode 133b is a cathode.

The electrode 133a is supported by and electrically connected to an electrode holder portion 137. The electrode holder portion 137 is electrically connected to the chamber 131 via a wiring, which is not illustrated. The electrode 133a supported by the electrode holder portion 137 is connected to a ground potential via the electrode holder portion 137, the wiring, which is not illustrated, and the chamber 131. The electrode 133b is fixed to a surface of a plate-shaped electrically insulating portion 135 on the internal space side of the chamber 131 with conductive members 157 formed of bolts, for example. The conductive members 157 are electrically connected to the pulse power module 143 and apply a high voltage from the pulse power module 143 to the electrode 133b.

The electrically insulating portion 135 includes an insulator. Examples of a material of the electrically insulating portion 135 may include alumina ceramics having low reactivity with F₂ gas. Note that it is only necessary for the electrically insulating portion 135 to have an electrically insulating property, and examples of a material of the electrically insulating portion 135 include resins such as a phenol resin and a fluororesin, quartz, and glass. The electrically insulating portion 135 closes an opening provided in the chamber 131 and is fixed to the chamber 131.

The charger 141 is a DC power source device that charges a charging capacitor, which is not illustrated, in the pulse power module 143 with a predetermined voltage. The pulse power module 143 includes a switch 143a controlled by the laser processor 190. When the switch 143a is switched from OFF to ON, the pulse power module 143 generates a pulsed high voltage from electric energy charged in the charge capacitor and applies the high voltage between the electrode 133a and the electrode 133b.

When the high voltage is applied between the electrode 133a and the electrode 133b, discharge occurs between the electrode 133a and the electrode 133b. The energy of the discharge excites the laser media in the chamber 131, and the excited laser media emit light when transitioning to the ground state.

A pair of windows 139a and 139b are provided in a wall surface of the chamber 131. The window 139a is located on a one end side of the chamber 131 in the traveling direction of the laser beam, the window 139b is located on the other end side in the traveling direction, and the windows 139a and 139b sandwich the space between the electrode 133a and the electrode 133b. The windows 139a and 139b are inclined to form a Brewster angle with respect to the traveling direction of the laser beam such that reflection of P-polarized light of the laser beam is suppressed. The oscillated laser beam as will be described later exits to the outside of the chamber 131 through the windows 139a and 139b.

The line narrowing module 145 includes a housing 145a, a prism 145b disposed in an internal space of the housing 145a, a grating 145c, and a rotation stage, which is not illustrated. An opening is formed in the housing 145a, and the housing 145a is connected to the chamber 131 on its rear side via the opening.

The prism 145b expands the beam width of the light exiting the window 139a and causes the light to be incident on the grating 145c. The prism 145b reduces the beam width of the light reflected from the grating 145c and returns the light to the internal space of the chamber 131 via the window 139a. The prism 145b is supported by the rotation stage and is rotated by the rotation stage. Rotation of the prism 145b changes the incident angle of the light with respect to the grating 145c. Thus, the wavelength of the light returned from the grating 145c through the prism 145b to the chamber 131 can be selected by the rotation of the prism 145b. Although FIG. 2 illustrates an example in which one prism 145b is disposed, it is only necessary for at least one prism to be disposed.

A surface of the grating 145c is formed of a material having a high reflectance, and a large number of grooves are formed on the surface at predetermined intervals. The sectional shape of each groove is, for example, a right triangle. The light that is incident on the grating 145c from the prism 145b is diffracted in a direction in accordance with the wavelength of the light when reflected by these grooves. The grating 145c is disposed in Littrow arrangement such that the incident angle of the light that is incident on the grating 145c from the prism 145b coincides with the diffracting angle of the diffracted light with a desired wavelength. This causes light near the desired wavelength to be returned to the chamber 131 through the prism 145b.

The output coupling mirror 147 is disposed in an internal space of an optical path pipe 147a connected to the chamber 131 on its front side and faces the window 139b. The output coupling mirror 147 transmits a part of the laser beam exiting the window 139b toward the monitor module 160 while reflecting the other part and returning it to the internal space of the chamber 131 through the window 139b. Thus, the grating 145c and the output coupling mirror 147 constitute a Fabry-Perot laser resonator, and the chamber 131 is disposed on the optical path of the laser resonator. The light from the chamber 131 travels to the monitor module 160.

The monitor module 160 is disposed on the optical path of the laser beam exiting the output coupling mirror 147. The monitor module 160 includes a plate-shaped base plate 161 along an HZ plane, a housing 162 disposed on a main surface of the base plate 161, a beam splitter 163 disposed in an internal space of the housing 162, a light condensing mirror, which is not illustrated, and an optical sensor 165.

The base plate 161 is disposed on a main surface of a plate-shaped optical plate 601 along the HZ plane and is slidable in an in-plane direction on the main surface of the optical plate 601. The optical plate 601 is disposed on a stand 603, and the stand 603 is disposed on a laser frame 111 of the accommodating portion 110. The optical plate 601 and the stand 603 are accommodated in the accommodating portion 110. Support members 605 that support the chamber 131 and the housing 145a are attached to the laser frame 111. Examples of materials of the optical plate 601, the stand 603, and the support members 605 include the same materials as those of the laser frame 111. Although the support members 605 are quadrangular prism members, the shape thereof is not particularly limited. Any members other than the monitor module 160 may not be disposed on the main surface of the optical plate 601.

An opening 162a is provided in the housing 162, and the internal space of the housing 162 communicates with the internal space of the optical path pipe 147a through the opening 162a. The laser beam exiting the output coupling mirror 147 passes through the opening 162a and travels to the internal space of the housing 162. In this manner, the opening 162a is an entrance region through which the laser beam from the chamber 131 generated by the excitation of the laser gas enters the internal space of the housing 162. The direction parallel to the optical axis of the laser beam traveling to the entrance region is the Z direction. An opening 162b is provided on a side of the housing 162 opposite to the side to which the optical path pipe 147a is connected, and the laser beam transmitted through the beam splitter 163 is transmitted through the opening 162b toward the shutter 170 as will be described later. In this manner, the opening 162b is an exit region through which the laser beam exits the internal space of the housing 162 to the external space. The opening 162b faces the opening 162a.

The beam splitter 163 transmits a part of the laser beam exiting the output coupling mirror 147 toward the shutter 170 while reflecting the other part of the laser beam toward the light condensing mirror. The light condensing mirror collects the laser beam from the beam splitter 163 on a light receiving surface of the optical sensor 165. The optical sensor 165 measures energy E of the laser beam that is incident on the light receiving surface and outputs a signal indicating the measured energy E to the laser processor 190.

The laser processor 190 of the present disclosure is a processing device including a storage device 190a that stores a control program and a central processing unit (CPU) 190b that executes the control program. The laser processor 190 is specifically configured or programmed to execute various kinds of processing included in the present disclosure. The laser processor 190 controls the entire gas laser device 100.

The laser processor 190 transmits and receives various signals to and from an exposure processor 230 of the exposure device 200. For example, the laser processor 190 receives, from the exposure processor 230, signals indicating a light emission trigger Tr, a target energy Et, and the like, which will be described later. The target energy Et is a target value of energy of the laser beam used in the exposure process. The laser processor 190 controls a charge voltage of the charger 141 on the basis of the energy E and the target energy Et received from the optical sensor 165 and the exposure processor 230. The energy of the laser light is controlled by controlling the charge voltage. In addition, the laser processor 190 transmits a command signal for turning ON or OFF a switch 143a to the pulse power module 143. The laser processor 190 is electrically connected to the shutter 170 and controls opening and closing of the shutter 170.

The laser processor 190 closes the shutter 170 until a difference ΔE between the energy E received from the monitor module 160 and the target energy Et received from the exposure processor 230 falls within an allowable range. If the difference ΔE falls within the allowable range, then the laser processor 190 transmits a reception preparation completion signal indicating that preparation for receiving the light emission trigger Tr has been completed to the exposure processor 230. The exposure processor 230 transmits a signal indicating the light emission trigger Tr to the laser processor 190 upon receiving the reception preparation completion signal, and the laser processor 190 opens the shutter 170 upon receiving the signal indicating the light emission trigger Tr. The light emission trigger Tr is defined by a predetermined repetition frequency f of the laser beam and a predetermined number of pulses P, and is a timing signal for the exposure processor 230 to cause the laser oscillator 130 to laser-oscillate, and is an external trigger. The repetition frequency f of the laser beam is equal to or greater than 100 Hz and equal to or less than 10 kHz, for example.

The shutter 170 is disposed in an optical path of the laser beam in the internal space of the optical path pipe 171 communicating with the opening 162b formed on the side of the housing 162 of the monitor module 160 opposite to the side to which the optical path pipe 147a is connected. The internal spaces of the optical path pipes 171 and 147a and the internal spaces of the housings 162 and 145a are supplied and filled with purge gas. The purge gas contains inert gas such as nitrogen (N₂) The purge gas is supplied from a purge gas supply source, which is not illustrated, through a pipe, which is not illustrated. Furthermore, the optical path pipe 171 communicates with the exposure device 200 through the opening of the accommodating portion 110 and an optical path pipe 500 connecting the accommodating portion 110 and the exposure device 200. The laser beam that has passed through the shutter 170 enters the exposure device 200.

The exposure processor 230 of the present disclosure is a processing device including a storage device 230a that stores a control program and a CPU 230b that executes the control program. The exposure processor 230 is specially configured or programmed to execute various kinds of processing included in the present disclosure. Also, the exposure processor 230 controls the entire exposure device 200.

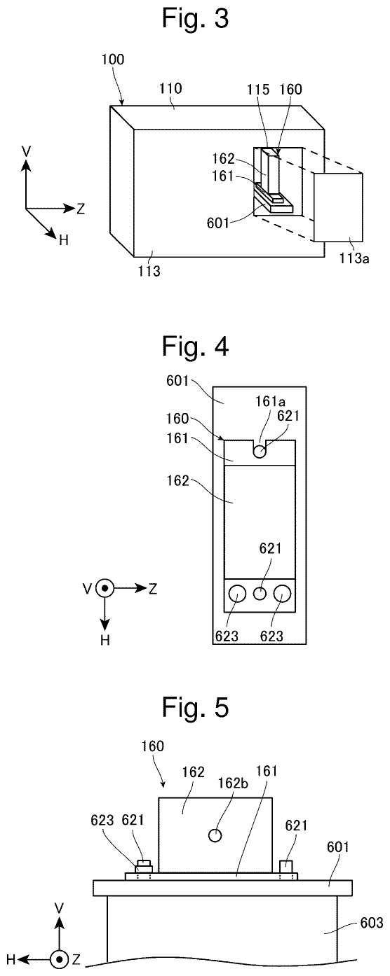

FIG. 3 is a perspective view of the gas laser device 100 of the comparative example. In FIG. 3, illustration of some of the members such as the optical path pipe 147a, the opening 162a, and the stand 603 is omitted. The accommodating portion 110 of the gas laser device 100 is covered with a cover 113 such as a panel attached to the laser frame 111 as described above. A part of the cover 113 located on, for example, the front surface out of the outer surfaces of the accommodating portion 110 is removable from the other part of the cover 113. FIG. 3 illustrates the removable part of the cover 113 as a cover 113a. An opening 115 is formed in the front surface of the accommodating portion 110 by removing the cover 113a. The monitor module 160 is installed in the accommodating portion 110 near the opening 115 in the front surface and can be loaded in and unloaded out of the accommodating portion 110 from the front surface through the opening 115 in a state where the cover 113a is removed. The monitor module 160 is loaded in and unloaded out of the accommodating portion 110 in a case where the monitor module 160 is subject to periodic maintenance or in a case where the monitor module 160 is replaced with another new monitor module 160.

The loading and unloading directions of the monitor module 160 are the H direction and a direction opposite to the H direction. In the loading and unloading directions of the monitor module 160, the side on which the monitor module 160 is taken out, in other words, the opening front surface side is defined as a closer side, and the side on which the monitor module 160 is pushed, in other words, the rear surface side is defined as a further side. Furthermore, the upstream in the traveling direction of the laser beam traveling from the output coupling mirror 147 to the shutter 170 via the monitor module 160 in the periphery of the monitor module 160 may be simply referred to as the upstream, and the downstream in the traveling direction of the laser beam may be simply referred to as the downstream for convenience of explanation.

FIG. 4 is a top view of the monitor module 160 of the comparative example, and FIG. 5 is a side view of the periphery of the monitor module 160 of the comparative example as viewed from the downstream. In FIG. 4 and FIG. 5, illustration of some of the members such as the optical path pipes 147a and 171 is omitted. The shapes of the main surface of the base plate 161 to which the housing 162 is fixed and the main surface of the optical plate 601 on which the base plate 161 is disposed are rectangular shapes elongated in the H direction. The base plate 161 is positioned on the optical plate 601 with a pair of positioning pins 621 and is then fixed to the optical plate 601 with a pair of fixing bolts 623. Illustration of the positioning pins 621 and the fixing bolts 623 is omitted in FIG. 3.

One of the positioning pins 621 is provided in advance to stand on the optical plate 601 on the pushing-in side in the loading and unloading directions of the monitor module 160. In addition, a notch 161a into which one of the positioning pins 621 is fitted is provided on the pushing-in side of the base plate 161. The one positioning pin 621 is located on the same line as the other positioning pin 621 and on the side opposite to the other positioning pin 621 with reference to the housing 162 in the loading and unloading directions of the monitor module 160. The other positioning pin 621 is inserted into the base plate 161 and the optical plate 601 on the pulling-out side in the loading and unloading directions of the monitor module 160 and positions the base plate 161 on the optical plate 601. The pair of fixing bolts 623 are provided on both sides of the other positioning pin 621 in the Z direction and fix the base plate 161 to the optical plate 601. The opening 162a of the housing 162, the beam splitter 163, and the opening 162b of the housing 162 are disposed on the optical path of the laser beam from the output coupling mirror 147 by the positioning achieved by the pair of positioning pins 621 and the fixing achieved by the pair of fixing bolts 623 described above.

### 2.2 Operations

Next, operations of the gas laser device 100 of the comparative example will be described.

The internal spaces of the optical path pipes 147a, 171, and 500 and the internal spaces of the housings 145a and 162 are filled with purge gas from a purge gas source, which is not illustrated, in a state before the gas laser device 100 outputs the laser beam. Furthermore, laser gas is supplied from a laser gas supply source, which is not illustrated, to the internal space of the chamber 131.

When the gas laser device 100 outputs a laser beam, the laser processor 190 receives the signal indicating the target energy Et and the signal indicating the light emission trigger Tr from the exposure processor 230. Furthermore, the laser processor 190 turns ON the switch 143a of the pulse power module 143. In this manner, the pulse power module 143 applies a pulsed high voltage between the electrode 133a and the electrode 133b from the electric energy charged in the charge capacitor, which is not illustrated. The high voltage causes discharge between the electrode 133a and the electrode 133b, and the laser media contained in the laser gas between the electrode 133a and the electrode 133b is brought into an excited state and emit light when the laser media return to the ground state. The light is amplified every time the light reciprocates between the grating 145c and the output coupling mirror 147 and passes through the discharge space in the internal space of the chamber 131, thereby causing laser oscillation. Then, a part of the laser beam passes through the output coupling mirror 147 as a pulsed laser beam, passes through the opening 162a of the housing 162, and travels toward the beam splitter 163.

A part of the laser beam having traveled to the beam splitter 163 is reflected by the beam splitter 163 and is received by the optical sensor 165. The optical sensor 165 measures the energy E of the received laser beam and outputs a signal indicating the energy E to the laser processor 190. The laser processor 190 controls the charge voltage such that the difference ΔE between the energy E and the target energy Et falls within the allowable range. Furthermore, the other part of the laser beam having traveled to the beam splitter 163 passes through the beam splitter 163, passes through the opening 162b of the housing 162 and the shutter 170, and travels to the exposure device 200.

### 2.3 Removal and Installation of Monitor Module

Next, removal and installation of the monitor module 160 of the comparative example will be described.

For the removal, the cover 113a is first detached from the opening 115 in the accommodating portion 110. Next, the pair of fixing bolts 623 are detached, and the fixing of the base plate 161 and the optical plate 601 achieved by the pair of fixing bolts 623 is released. When the fixing is released, the other positioning pin 621 on the closer side is detached from the base plate 161 and the optical plate 601, and the monitor module 160 is pulled out from the internal space of the accommodating portion 110 to the external space of the accommodating portion 110 through the opening 115. At this time, the base plate 161 slides in the H direction on the main surface of the optical plate 601, and the monitor module 160 is removed.

For the installation, when the removed monitor module 160 is subjected to maintenance or is replaced with another new monitor module 160, the monitor module 160 is pushed into the internal space of the accommodating portion 110 through the opening 115 from the external space of the accommodating portion 110 in a manner opposite to the above. At this time, the base plate 161 slides in the H direction on the main surface of the optical plate 601, and one of the positioning pins 621 on the further side is fitted to the notch 161a. Next, the other positioning pin 621 on the closer side is inserted into the base plate 161 and the optical plate 601 to position the base plate 161 on the optical plate 601. Next, the pair of fixing bolts 623 fix the base plate 161 to the optical plate 601. In this manner, the opening 162a of the housing 162, the beam splitter 163, and the opening 162b of the housing 162 are disposed on the optical path of the laser beam exiting the output coupling mirror 147, and the installation of the monitor module 160 is completed. Finally, the cover 113a is attached to the opening 115.

### 2.4 Problems

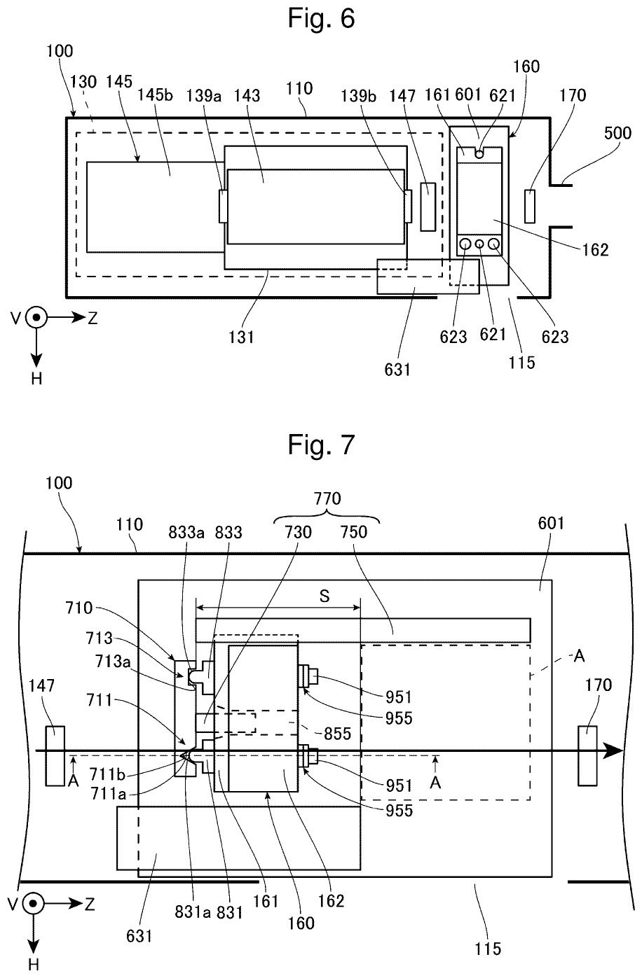

FIG. 6 is a top view of the internal space of the accommodating portion 110 of the gas laser device 100. In FIG. 6, illustration of members such as the optical path pipes 147a and 171, electrodes 133a and 133b and the like disposed in the internal space of the chamber 131, and the grating 145c, the beam splitter 163, and the like disposed in the internal spaces of the housings 145a and 162 is omitted.

The gas laser device 100 is required to have high functionality and multi-functionality. For this reason, existing modules such as the laser oscillator 130 and the monitor module 160 mounted on the gas laser device 100 have increased sizes, modules are added separately from the existing modules, and there is a trend that the number of modules in the gas laser device 100 increases. Such an added module may be referred to as a newly installed module 631 below. In a case where the newly installed module 631 is installed inside the accommodating portion 110 to close a part of the opening 115 in front surface of the accommodating portion 110, and the monitor module 160 is installed at a predetermined position behind the newly installed module 631, the field of view behind the newly installed module 631 is blocked by the newly installed module 631. Therefore, it is difficult to move the monitor module 160 to the predetermined position. In addition, in a case where the base plate 161 is fixed to the optical plate 601 at the predetermined position using the notch 161a, the pair of positioning pins 621, and the pair of fixing bolts 623, and the field of view is blocked as described above, it takes time and effort to perform the work of fixing the monitor module 160 in the internal space of the accommodating portion 110. Therefore, facilitating the movement of the monitor module 160 to the predetermined position in the accommodating portion 110 and reducing the time and effort for the work of fixing the monitor module 160 are required.

Thus, a gas laser device 100 capable of facilitating the movement of the monitor module 160 to the predetermined position in the accommodating portion 110 and reducing the time and effort for the work of fixing the monitor module 160 will be described as an example in the following embodiment.

### 3. Description of Gas Laser Device of Embodiment

Next, the gas laser device 100 of the present embodiment will be described. Note that the same configurations as those described above will be denoted by the same reference signs, and repeated description will be omitted except for a case of special description. Furthermore, some of members may be omitted or simplified for easiness in viewing in some drawings.

### 3.1 Configurations

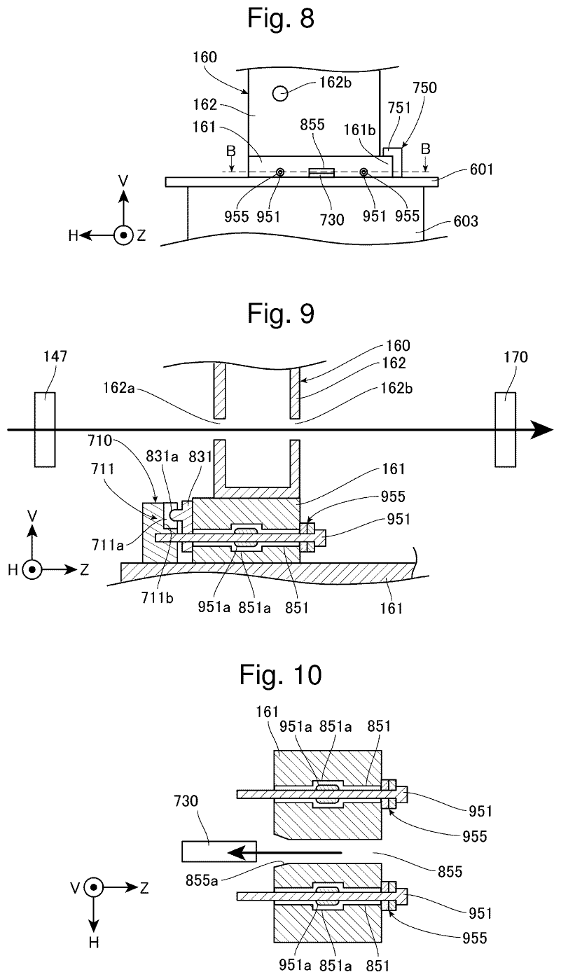

FIG. 7 is a top view of a periphery of a monitor module 160 according to the present embodiment. FIG. 8 is a side view of the periphery of the monitor module 160 illustrated in FIG. 7 as viewed from the downstream. FIG. 9 is a sectional view taken along the line A-A illustrated in FIG. 7. In FIGS. 7 and 9, a laser beam traveling from an output coupling mirror 147 to a shutter 170 via the monitor module 160 is indicated by the thick arrows. In FIG. 7, illustration of the cover 113a is omitted. Furthermore, the thick arrow indicating the laser beam originally overlaps the line A-A illustrated in FIG. 7 in the top view illustrated in FIG. 7, the arrow is offset from the line A-A illustrated in FIG. 7 in the illustration for clarity.

In the gas laser device 100 of the present embodiment, a configuration of a base plate 161 is different from the configuration of the base plate 161 of the comparative example. The gas laser device 100 of the present embodiment is different from the gas laser device 100 of the comparative example in that the gas laser device 100 of the present embodiment further includes a positioning member 710 and a guide 770 including a first guide member 730 and a second guide member 750.

The positioning member 710 and the guide 770 are disposed on the main surface of the optical plate 601. The monitor module 160, the positioning member 710, and the first guide member 730 are installed at predetermined positions behind the newly installed module 631, and the second guide member 750 is installed behind the first guide member 730 and the monitor module 160. Incidentally, a part of the opening 115 is closed by the newly installed module 631, and the other part of the opening 115 is not closed by the newly installed module 631 in the opening 115 of the present embodiment similarly to the comparative example. It is assumed that the part of the opening 115 of the present embodiment is located on the side further upstream than the other part of the opening 115. In a case where the accommodating portion 110 is viewed from the opening 115, the monitor module 160, the positioning member 710, the first guide member 730, and the second guide member 750 are partially shielded by the newly installed module 631. Furthermore, the other part of the second guide member 750 is exposed without being hidden by the newly installed module 631.

Hereinafter, the left side surface of each of the base plate 161 and the housing 162 when viewed from the front surface may be referred to as an upstream side surface, and the right side surface thereof may be referred to as a downstream side surface for convenience of explanation.

In the monitor module 160, the housing 162 has a rectangular parallelepiped shape, the upper surface and the bottom surface of the housing 162 are along the HZ plane, and the shapes thereof are rectangular shapes elongated in the H direction. The front surfaces of the base plate 161 and the housing 162 are located in the same plane, and the downstream surfaces thereof are also located in the same plane. However, the rear surface of the base plate 161 is located on the further side than the rear surface of the housing 162, and the upstream side surface of the base plate 161 is located on the side further upstream than the upstream side surface of the housing 162. Therefore, the base plate 161 extends further upstream and on the further side than the housing 162.

The monitor module 160 is installed on the side further downstream than the positioning member 710. The upstream side surface of the base plate 161 faces the positioning member 710, and a first spherical pin 831 and a second spherical pin 833 are fixed to the upstream side surface with fixing bolts, which are not illustrated. Therefore, the first spherical pin 831 and the second spherical pin 833 are provided at positions deviating from the opening 162a as the entrance region provided in the upstream side surface of the housing 162. In the present embodiment, the first spherical pin 831 and the second spherical pin 833 are provided further downward in the direction of gravity than the opening 162a. In addition, the first spherical pin 831 and the second spherical pin 833 are disposed to face and be spaced apart from each other on the respective sides of an extension line of the central axis of the base plate 161 along the Z direction. The first spherical pin 831 and the second spherical pin 833 protrude upstream, that is, toward the positioning member 710 from the upstream side surface of the base plate 161 and have the same length in the Z direction. Although the first spherical pin 831 and the second spherical pin 833 are disposed at the same position in the Z direction and the V direction, the first spherical pin 831 and the second spherical pin 833 may be disposed with deviation. The first spherical pin 831 is disposed on the closer side than the second spherical pin 833.

Each of the first spherical pin 831 and the second spherical pin 833 has a columnar shape, each of distal ends thereof has a semicylindrical shape, and the first spherical pin 831 and the second spherical pin 833 include curved surfaces 831a and 833a, respectively, at their distal ends. The curved surfaces 831a and 833a are, for example, curved surfaces with semicircular sections, and in other words, the horizontal sectional shapes of their distal ends are arc shapes. The curved surface 831a of the first spherical pin 831 abuts on a V-shaped groove abutting portion 711, which will be described later, of the positioning member 710, and the curved surface 833a of the second spherical pin 833 abuts on a planar abutting portion 713, which will be described later, of the positioning member 710.

The positioning member 710 includes the V-shaped groove abutting portion 711 that abuts on the first spherical pin 831 at two points and the planar abutting portion 713 that abuts the second spherical pin 833 at one location. The V-shaped groove abutting portion 711 and the planar abutting portion 713 are provided on the downstream side surface of the positioning member 710, and the downstream side surface faces the upstream side surface of the base plate 161.

The horizontal sectional shape of the part of the V-shaped groove abutting portion 711 abutting the first spherical pin 831 is a V shape, and the V-shaped groove of the V-shaped groove abutting portion 711 is recessed from the downstream side toward the upstream side. An inner surface 711a of the V-shaped groove abuts on the curved surface 831a of the first spherical pin 831 at two points when the monitor module 160 moves toward the positioning member 710.

The line along which the two surfaces constituting the inner surface 711a of the V-shaped groove of the V-shaped groove abutting portion 711 are in contact with each other is perpendicular to the main surface of the optical plate 601 on which the monitor module 160 slides, and an apex 711b of the V-shaped groove is located in the VZ plane including the optical axis of the laser beam. The openings 162a and 162b and the first spherical pin 831 are also located in the VZ plane. The positioning member 710 is fixed to the optical plate 601 on the side further upstream than the monitor module 160 with a fixing bolt, which is not illustrated, such that the apex 711b of the V-shaped groove is located in the VZ plane.

The horizontal sectional shape of the part of the planar abutting portion 713 abutting the second spherical pin 833 is a recessed shape, and the recessed portion of the planar abutting portion 713 is recessed from the downstream side toward the upstream side. A bottom surface 713a of the planar abutting portion 713 on which the second spherical pin 833 abuts is a flat surface. The bottom surface 713a abuts the curved surface 833a of the second spherical pin 833 at one location when the monitor module 160 moves toward the positioning member 710.

When the first spherical pin 831 abuts on the V-shaped groove abutting portion 711, and the second spherical pin 833 abuts on the planar abutting portion 713, the positioning member 710 positions the monitor module 160 at a predetermined position on the optical plate 601. Furthermore, the monitor module 160 is fixed in the internal space of the accommodating portion 110 through screwing of the positioning member 710 to fixing members 951, which will be described later, in a state where the first spherical pin 831 abuts on the V-shaped groove abutting portion 711 and the second spherical pin 833 abuts on the planar abutting portion 713.

FIG. 10 is a sectional view taken along the line B-B illustrated in FIG. 8. In FIG. 10, illustration of the positioning member 710 and the second guide member 750 is omitted, and a state where the first guide member 730 is not inserted into a guide groove 855, which will be described later, is illustrated. In FIG. 10, a state of movement of the base plate 161 toward the first guide member 730 is indicated by the thick arrow.

The base plate 161 is provided with through-holes 851 that penetrate through the base plate 161 in the Z direction. Although an example in which two through-holes 851 are provided in parallel is illustrated in the present embodiment, it is only necessary for at least one through-hole 851 to be provided. In a top view of the through-holes 851, the through-holes 851 are provided in parallel on the respective sides of the guide groove 855, which will be described later. Note that in FIG. 7, illustration of the through-holes 851 is omitted.

The fixing members 951 that are fixing bolts, for example, individually penetrate through the through-holes 851, respectively. The fixing members 951 are inserted into the through-holes 851 from the exit region side, that is, from the downstream side, and protrude from the entrance region side, that is, from the upstream side. A pair of spherical washers 955 are disposed between a head of each fixing member 951 and the base plate 161. Seating surfaces of the spherical washers 955 on the side on which the spherical washers 955 face each other are projecting and recessed spherical surfaces. Misalignment of the fixing members 951 with respect to the through-holes 851 is absorbed by the spherical washers 955, and the fixing members 951 move in the Z direction together with the spherical washers 955.

A part of each through-hole 851 is provided with an enlarged diameter portion 851a, the diameter of which is larger than the other part. Each fixing member 951 is provided with a set collar 951a disposed in the enlarged diameter portion 851a. Dropping of the fixing member 951 from the through-hole 851 when the monitor module 160 slides on the main surface of the optical plate 601, for example, is suppressed by the set collar 951a. Note that the enlarged diameter portion 851a and the set collar 951a may not be provided.

Each through-hole 851 is provided in the base plate 161 as described above. Therefore, the through-hole 851 is provided at a position deviating from the opening 162a as the entrance region provided in the upstream side surface of the housing 162 and the opening 162b as the exit region provided in the downstream side surface of the housing 162 as illustrated in FIG. 9. In the present embodiment, the through-hole 851 is provided on the side further downward in the direction of gravity than the openings 162a and 162b. The through-hole 851 on the closer side illustrated in FIG. 9 is provided on the side further downward in the direction of gravity than the first spherical pin 831 and the V-shaped groove abutting portion 711. The fixing member 951 on the closer side penetrating through the through-hole 851 is screwed into the positioning member 710 at a position that is lower in the direction of gravity than the V-shaped groove abutting portion 711. The through-hole 851 on the closer side and the fixing member 951 on the closer side are located in the aforementioned VZ plane in which the apex 711b of the V-shaped groove of the V-shaped groove abutting portion 711 is located. Note that although not described in the drawing, the through-hole 851 on the further side is provided on the side further downward in the direction of gravity than the second spherical pin 833 and the planar abutting portion 713, the fixing member 951 on the further side penetrating through the through-hole 851 is screwed into the positioning member 710 at a position that is lower in the direction of gravity than the planar abutting portion 713. It is only necessary for each fixing member 951 to be screwed into the positioning member 710 at a position lower in the direction of gravity than one of the V-shaped groove abutting portion 711 and the planar abutting portion 713, the one being at a lower position in the direction of gravity than the other thereof. In addition, it is only necessary for each through-hole 851 to be provided on the side further downward in the direction of gravity than the abutting portion.

As illustrated in FIGS. 8 and 10, the bottom surface of the base plate 161 that is placed on the main surface of the optical plate 601 is provided with the guide groove 855 that straddles the first guide member 730 when the monitor module 160 moves toward the positioning member 710. The guide groove 855 is along the Z direction similarly to the through-holes 851 and is provided from the upstream side surface to the downstream side surface of the base plate 161. Although the guide groove 855 is located at the same height position as those of the through-holes 851 in the V direction, the guide groove 855 may be located at a deviating position. As illustrated in FIG. 8, the VH sectional shape of the guide groove 855 is a rectangular shape elongated in the H direction. Note that the shape of the guide groove 855 is not particularly limited.

As illustrated in FIG. 10, an end of the guide groove 855 on the advancing side to the first guide member 730, that is, an upstream end of the guide groove 855 is provided with a tapered portion 855a. The width of the tapered portion 855a in the H direction is reduced from the upstream end of the guide groove 855 toward the downstream end on the side opposite to the upstream end. The tapered portion 855a can facilitate insertion of the first guide member 730 into the guide groove 855 when the monitor module 160 advances toward the first guide member 730.

Since the guide groove 855 is provided in the base plate 161, the guide groove 855 is provided at a position deviating from the openings 162a and 162b similarly to the through-holes 851.

As illustrated in FIG. 7, the guide 770 extends in the Z direction. The monitor module 160 slides on the optical plate 601 in the H direction from the other part of the opening 115 up to a predetermined region A and then slides in the Z direction toward the positioning member 710 spaced apart from the predetermined region A by a predetermined section S in the Z direction along the guide 770. In other words, the guide 770 guides the monitor module 160 in the Z direction toward the positioning member 710. The predetermined section S is a section that is hidden by the newly installed module 631 in a section located on the side further downstream than the positioning member 710 when the accommodating portion 110 is viewed from the opening 115. Therefore, in a case where the accommodating portion 110 is viewed from the opening 115, the downstream end of the predetermined section S overlaps the downstream end of the newly installed module 631 and the boundary between a part of the opening 115 closed by the newly installed module 631 and the other part of the opening 115 that is not closed by the newly installed module 631.

The first guide member 730 of the guide 770 extends in the Z direction and is disposed in a region on the optical plate 601 where the monitor module 160 moves in the Z direction. Specifically, the first guide member 730 is disposed on the optical plate 601 in the predetermined section S from the positioning member 710 in the Z direction. Therefore, the first guide member 730 is disposed on the side further downstream than the positioning member 710. Although the first guide member 730 is shorter than the length from the positioning member 710 to the downstream end of the predetermined section S in the Z direction in the present embodiment, the first guide member 730 may extend from the positioning member 710 to the downstream end of the predetermined section S. The monitor module 160 slides in the Z direction along the first guide member 730 when the monitor module 160 moves toward the positioning member 710. At this time, the inner surface of the guide groove 855 of the monitor module 160 slides along the first guide member 730 as described above. In this manner, the first guide member 730 guides the monitor module 160 to the positioning member 710 in the Z direction.

The upstream end of the first guide member 730 abuts on the positioning member 710. The downstream end of the first guide member 730 is located inside the guide groove 855. Therefore, a part of the first guide member 730 is exposed from the monitor module 160, and another part is located immediately below the monitor module 160. Note that the downstream end of the first guide member 730 may be located on the side further downstream than the guide groove 855. The first guide member 730 is fixed to the optical plate 601 between the V-shaped groove abutting portion 711 and the planar abutting portion 713 with a fixing bolt, which is not illustrated. The first guide member 730 is a quadrangular prism member extending in the Z direction, and the VH sectional shape is a rectangular shape elongated in the H direction. The first guide member 730 is shorter than the second guide member 750 and the newly installed module 631 in the Z direction. Examples of a material of the first guide member 730 include the same materials as those of the laser frame 111. Note that the shape of the first guide member 730 is not particularly limited.

The second guide member 750 extends in the Z direction from the inside of the predetermined section S to outside of the predetermined section S. A part of the second guide member 750 on the upstream side is aligned with the first guide member 730, the second guide member 750 is longer than the first guide member 730, and a part thereof on the downstream side is located behind the predetermined region A outside the predetermined section S. The base plate 161 of the monitor module 160 comes into contact with the second guide member 750 in the H direction in the predetermined region A outside the predetermined section S. In this manner, the second guide member 750 restricts movement of the monitor module 160 on the further side than the second guide member 750 and prevents the monitor module 160 from colliding against the rear surface of the accommodating portion 110. Furthermore, the second guide member 750 positions the monitor module 160 in the H direction such that the first spherical pin 831, the through-hole 851 on the closer side, and the fixing member 951 on the closer side penetrating through the through-hole 851 are located in the VZ plane where the apex 711b of the V-shaped groove is located.

When the monitor module 160 is installed, the monitor module 160 comes into contact with the second guide member 750 in the predetermined region A, and the monitor module 160 then slides along the second guide member 750 in the Z direction. At this time, the base plate 161 of the monitor module 160 slides along the second guide member 750. In this manner, the second guide member 750 guides the monitor module 160 to the first guide member 730 in the Z direction. Also, the second guide member 750 guides the monitor module 160 to the positioning member 710 in the Z direction.

As illustrated in FIG. 8, the second guide member 750 has an L-shaped VH sectional shape. The second guide member 750 includes a cover portion 751 that covers an abutting portion 161b of the monitor module 160 away from the optical plate 601 in the V direction perpendicular to the optical plate 601 in a state where the abutting portion 161b abuts on the second guide member 750. The abutting portion 161b is a portion of the base plate 161 that extends further than the housing 162 in the H direction. The cover portion 751 covers the abutting portion 161b, thereby suppressing falling-down of the monitor module 160. Although the cover portion 751 is not in contact with the rear surface of the housing 162, the cover portion 751 may be in contact therewith.

The second guide member 750 is fixed to the optical plate 601 with a fixing bolt, which is not illustrated. Examples of a material of the second guide member 750 include the same materials as those of the laser frame 111. Note that the shape of the second guide member 750 is not particularly limited.

### 3.2 Removal and Installation of Monitor Module

Next, removal and installation of the monitor module 160 in the present embodiment will be described. The removal and the installation are performed in a state where a part of the opening 115 of the accommodating portion 110 is closed by the newly installed module 631 and another part of the opening 115 is not closed by the newly installed module 631.

In the removal, the cover 113a is detached from the opening 115 in the accommodating portion 110 similarly to the comparative example. Next, the screwing between the fixing members 951 and the positioning member 710 is released, and the fixing between the base plate 161 and the positioning member 710 achieved by the fixing members 951 is released. In this case, an operator who loads and unloads the monitor module 160 inserts his/her hand into the internal space of the accommodating portion 110 through the other part of the opening 115 from the external space of the accommodating portion 110 and detaches the fixing members 951 from the positioning member 710.

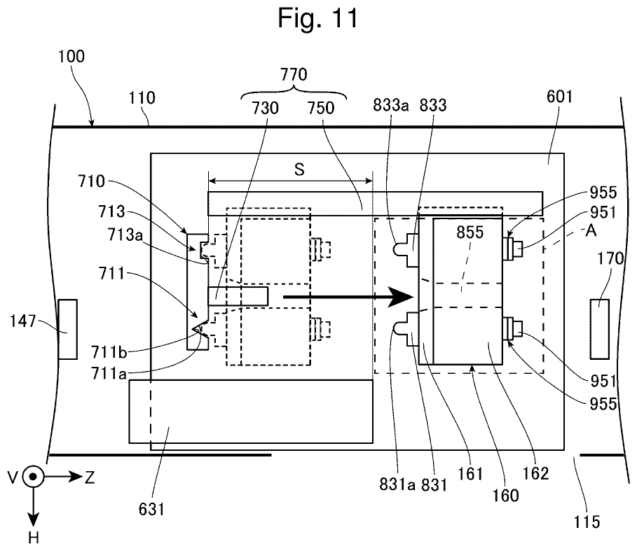

FIG. 11 is a diagram for explaining a part of a removal operation of the monitor module 160 in the present embodiment. If the fixing achieved by the fixing members 951 is released, then the base plate 161 slides on the main surface of the optical plate 601 in the Z direction toward the downstream side. In FIG. 11, the monitor module 160 before the sliding is indicated by the dashed line, the monitor module 160 after the sliding is indicated by the solid line, and the state of the sliding of the monitor module 160 is indicated by the thick arrow. In the operation illustrated in FIG. 11, the monitor module 160 is pulled downstream, the guide groove 855 slides along the first guide member 730, and the base plate 161 slides along the second guide member 750. The sliding of the guide groove 855 along the first guide member 730 prevents the monitor module 160 from moving to the closer side and colliding against the newly installed module 631. Furthermore, the sliding of the base plate 161 along the second guide member 750 facilitates the moving of the base plate 161 toward the downstream side in the Z direction. The base plate 161 slides from the inside of the predetermined section S to the predetermined region A outside the predetermined section S such that the base plate 161 overlaps the other part of the opening 115 when viewed from the opening 115.

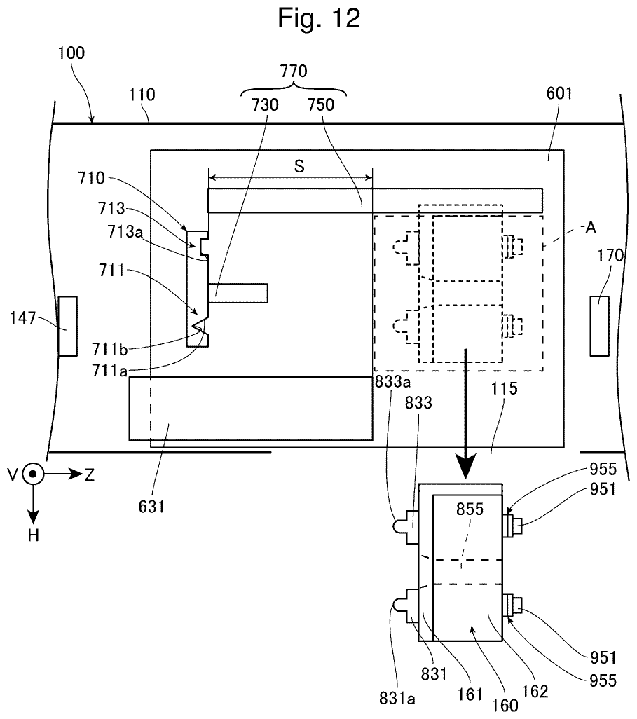

FIG. 12 is a diagram for explaining another part of the removal operation of the monitor module 160 in the present embodiment. The monitor module 160 is pulled out from the predetermined region A in the internal space of the accommodating portion 110 to the external space of the accommodating portion 110 through the other part of the opening 115. In FIG. 12, the monitor module 160 before the pulling-out is indicated by the dashed line, the monitor module 160 after the pulling-out is indicated by the solid line, and the state of the pulling-out of the monitor module 160 is indicated by the thick arrow. The monitor module 160 illustrated by the dashed line in FIG. 12 is the monitor module 160 illustrated by the solid line in FIG. 11. In the operation illustrated in FIG. 12, the base plate 161 slides on the main surface of the optical plate 601 in the H direction, and the monitor module 160 is removed similarly to the comparative example.

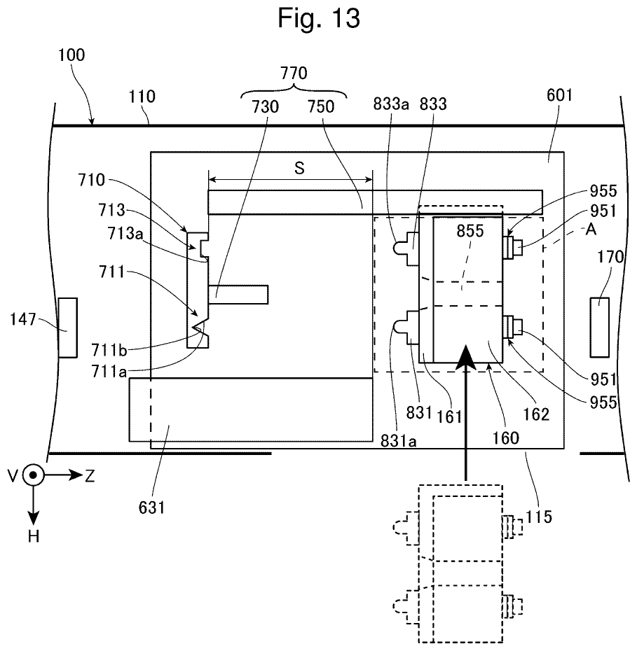

FIG. 13 is a diagram for explaining a part of the installation operation of the monitor module 160 in the present embodiment. If the removed monitor module 160 is subjected to maintenance or is replaced with another new monitor module 160, then the monitor module 160 is pushed into the internal space of the accommodating portion 110 from the external space of the accommodating portion 110 through the other part of the opening 115 in a manner opposite to the above. In FIG. 13, the monitor module 160 before the pushing-in is indicated by the dashed line, the monitor module 160 after the pushing-in is indicated by the solid line, and the state of the pushing-in of the monitor module 160 is indicated by the thick arrow. The monitor module 160 indicated by the dashed line in FIG. 13 is the monitor module 160 indicated by the solid line in FIG. 12. The monitor module 160 indicated by the solid line in FIG. 13 is the monitor module 160 indicated by the dashed line in FIG. 12. In the operation illustrated in FIG. 13, the base plate 161 slides on the main surface of the optical plate 601 to the predetermined region A in the H direction and abuts on the second guide member 750. In this manner, movement of the monitor module 160 on the further side than the second guide member 750 is restricted, and the monitor module 160 is prevented from colliding against the rear surface of the accommodating portion 110. If the base plate 161 abuts on the second guide member 750, then the cover portion 751 of the second guide member 750 covers the abutting portion 161b of the base plate 161 that extends further than the housing 162 in the H direction. In this manner, falling-down of the monitor module 160 is suppressed by the second guide member 750.

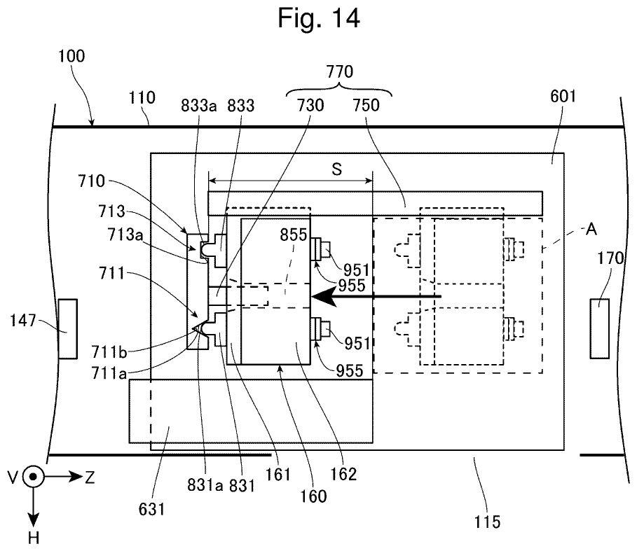

FIG. 14 is a diagram for explaining another part of the installation operation of the monitor module 160 in the present embodiment. The base plate 161 slides along the second guide member 750 in the Z direction and is guided by the second guide member 750 from the predetermined region A to the first guide member 730 and the positioning member 710 disposed in the predetermined section S. In FIG. 14, the monitor module 160 before the sliding is indicated by the dashed line, the monitor module 160 after the sliding is indicated by the solid line, and the state of the sliding of the monitor module 160 is indicated by the thick arrow. The monitor module 160 indicated by the dashed line in FIG. 14 is the monitor module 160 indicated by the solid line in FIG. 13. In the operation illustrated in FIG. 14, the monitor module 160 is pushed upstream. If the monitor module 160 reaches the first guide member 730, then the guide groove 855 slides along the first guide member 730. Since the upstream end of the guide groove 855 is provided with the tapered portion 855a, the first guide member 730 is easily inserted into the guide groove 855. If the guide groove 855 slides along the first guide member 730, then the base plate 161 is guided to the positioning member 710 by the first guide member 730. At this time, the base plate 161 also slides along the second guide member 750 in the Z direction and is also guided to the positioning member 710 by the second guide member 750.

If the base plate 161 slides to the positioning member 710, then the curved surface 831a of the first spherical pin 831 abuts on the inner surface 711a of the V-shaped groove of the V-shaped groove abutting portion 711. In this manner, the monitor module 160 is positioned in the H direction. The curved surface 833a of the second spherical pin 833 abuts on the bottom surface 713a of the recessed portion of the planar abutting portion 713. In this manner, the monitor module 160 is positioned in the Z-direction and in the direction around V.

The second spherical pin 833 is disposed at the same position as that of the first spherical pin 831 in the Z direction, and the planar abutting portion 713 is disposed at the same position as that of the V-shaped groove abutting portion 711 in the Z direction. In a case where the monitor module 160 slides toward the positioning member 710, the abutting between the curved surface 833a of the second spherical pin 833 and the bottom surface 713a of the planar abutting portion 713 concurrently occurs with the abutting between the curved surface 831a of the first spherical pin 831 and the inner surface 711a of the V-shaped groove abutting portion 711. Note that in a case where the monitor module 160 slides toward the positioning member 710 while being inclined with respect to the Z direction, one of the abutting between the second spherical pin 833 and the planar abutting portion 713 and the abutting between the first spherical pin 831 and the V-shaped groove abutting portion 711 is achieved earlier than the other thereof. If the monitor module 160 rotates about the V direction around the previously abutting portion, then the other abutting is achieved. In a case where the curved surface 831a abuts on the inner surface 711a earlier than the abutting of the curved surface 833a against the bottom surface 713a, for example, the monitor module 160 rotates about the V direction around the curved surface 831a. In this manner, the curved surface 833a abuts on the bottom surface 713a while the curved surface 831a abuts on the inner surface 711a. In a case where the curved surface 833a abuts on the bottom surface 713a earlier than the abutting of the curved surface 831a on the inner surface 711a in a manner opposite to the above, the monitor module 160 rotates about the V direction around the curved surface 833a. In this manner, the curved surface 833a rolls about the V direction on the bottom surface 713a, and the curved surface 831a abuts on the inner surface 711a.

Next, the fixing member 951 penetrating through the through-hole 851 on the closer side is screwed into the positioning member 710 through rotation around the longitudinal axis of the fixing member 951 in a state where the curved surface 831a of the first spherical pin 831 abuts on the inner surface 711a of the V-shaped groove of the V-shaped groove abutting portion 711 at two points. At this time, the fixing member 951 is inserted into the positioning member 710 in the Z direction by unevenness of the spherical washers 955. If the head of the fixing member 951 abuts on the spherical washers 955, and the spherical washers 955 abut on the base plate 161, then the advancing of the fixing member 951 in the Z direction is stopped. If the fixing member 951 further rotates about the longitudinal axis of the fixing member 951 in this state, then the base plate 161 is pushed toward the positioning member 710 through screwing between the fixing member 951 and the positioning member 710. In other words, the fixing member 951 pushes the base plate 161 toward the positioning member 710. In this manner, the curved surface 831a of the first spherical pin 831 is pressed against the inner surface 711a of the V-shaped groove of the V-shaped groove abutting portion 711 such that the curved surface 831a abuts thereon at two points, and the monitor module 160 is fixed in the H direction.

Furthermore, the fixing member 951 penetrating through the through-hole 851 on the further side is screwed into the positioning member 710 through rotation about the longitudinal axis of the fixing member 951 in a state where the curved surface 833a of the second spherical pin 833 abuts on the bottom surface 713a of the recessed portion of the planar abutting portion 713. Similarly to the first spherical pin 831, the curved surface 833a of the second spherical pin 833 is pressed against the bottom surface 713a of the recessed portion of the planar abutting portion 713, and the monitor module 160 is fixed in the Z direction and around the V direction.

As described above, the monitor module 160 is positioned and fixed at the predetermined position in the internal space of the accommodating portion 110, and the opening 162a, the beam splitter 163, and the opening 162b are disposed on the optical path of the laser beam from the output coupling mirror 147, and the installation of the monitor module 160 is completed. Finally, the cover 113a is attached to the opening 115.

### 3.3 Effects and Advantages

The guide 770 of the present embodiment extends in the Z direction parallel to the optical axis of the light and guides the monitor module 160 toward the positioning member 710 in the Z direction. Furthermore, the monitor module 160 slides on the optical plate 601 to the predetermined region A in the H direction perpendicularly intersecting the Z direction and then slides along the guide 770 in the Z direction toward the positioning member 710 spaced apart from the predetermined region A in the Z direction. Also, the monitor module 160 is fixed in the internal space of the accommodating portion 110 through screwing of the fixing members 951 penetrating through the through-holes 851 to the positioning member 710.

In the gas laser device 100 of the present embodiment, the monitor module 160 is caused to slide on the main surface of the optical plate 601 to the predetermined region A in the H direction, and the monitor module 160 is then caused to move in the Z direction. In the movement in the Z direction, the monitor module 160 slides along the guide 770 from the predetermined region A toward the positioning member 710. This can facilitate movement of the monitor module 160 in the Z direction, can facilitate the monitor module 160 to a predetermined position where visibility behind the newly installed module 631 is limited, and can facilitate abutting of the monitor module 160 on the positioning member 710. In addition, the monitor module 160 is fixed in the internal space of the accommodating portion 110 by the fixing members 951 being screwed into the positioning member 710 on which the monitor module 160 abuts. With this configuration, it is only necessary to screw the fixing members 951 to the positioning member 710 regardless of the limited visibility as compared with a case where the monitor module 160 is fixed to the optical plate 601 with the notch 161a, the positioning pins 621, and the fixing bolts 623 as in the comparative example, and it is thus possible to reduce the time and effort to perform the work of fixing the monitor module 160 in the internal space of the accommodating portion 110. Incidentally, it is assumed that, unlike the gas laser device 100 of the present embodiment, the through-holes 851 penetrate through the monitor module 160 in the H direction and the fixing members 951 penetrate through the through-holes 851 and are screwed into the positioning member 710 located behind the monitor module 160. In this case, it is necessary for the operator to perform a work of inserting his/her hand between the monitor module 160 and the newly installed module 631 to screw the fixing member 951 into the positioning member 710. Therefore, the gas laser device 100 of the present embodiment can reduce the time and effort for the work of fixing the monitor module 160 as compared with the case where the through-holes 851 penetrate through the monitor module 160 in the H direction and the fixing members 951 penetrate through the through-holes 851 and are screwed into the positioning member 710. As described above, the gas laser device 100 can facilitate the movement of the monitor module 160 to the predetermined position in the accommodating portion 110 and reduce the time and effort for the work of fixing the monitor module 160.

Further, in the gas laser device 100 of the present embodiment, the line along which the two surfaces constituting the inner surface 711a of the V-shaped groove of the V-shaped groove abutting portion 711 are in contact with each other is perpendicular to the main surface of the optical plate 601 on which the monitor module 160 slides, and the apex 711b of the V-shaped groove is located in the VZ plane including the optical axis of the laser beam.

In the gas laser device 100 of the present embodiment, when the laser beam from the chamber 131 travels to the monitor module 160, the temperature of the monitor module 160 may increase due to the laser beam, scattered light thereof, or the like in the internal space of the accommodating portion 110. As a result, the monitor module 160 may be deformed due to thermal expansion. According to the above configuration, the monitor module 160 is constrained with reference to the VZ plane including the optical axis of the laser beam, and deviation of the opening 162a, the beam splitter 163, and the opening 162b from the optical axis can be suppressed even if the monitor module 160 is deformed due to the heat. In this manner, even if deformation of the monitor module 160 due to thermal expansion occurs, fluctuations in the laser light output from the gas laser device 100 can be suppressed. Note that the apex 711b may not be located in the above VZ plane.

Furthermore, in the gas laser device 100 of the present embodiment, the fixing members 951 are screwed into the positioning member 710 at the positions lower in the direction of gravity than one abutting portion of the V-shaped groove abutting portion 711 and the planar abutting portion 713 located at a lower position in the direction of gravity than the position of the other abutting portion.

With this configuration, a clockwise force when viewed from the front surface in the H direction around the abutting portion of the V-shaped groove abutting portion 711 and the planar abutting portion 713 that is located at a lower position in the direction of gravity than the position of the other abutting portion is applied to the monitor module 160 in a case where the fixing members 951 are screwed into the positioning member 710. The monitor module 160 is further pressed against the optical plate 601 as it is spaced apart from the positioning member 710 due to the clockwise force. Therefore, the displacement of the monitor module 160 in the H direction can be suppressed as compared with a case where the clockwise force is not applied to the monitor module 160. Also, the first spherical pin 831 and the second spherical pin 833 are disposed further upward than the fixing members 951. Therefore, the abutting state between the first spherical pin 831 and the V-shaped groove abutting portion 711 can be easily visually recognized from above the V-shaped groove abutting portion 711, and the abutting state between the second spherical pin 833 and the planar abutting portion 713 can be easily visually recognized from above the planar abutting portion 713. Note that the fixing members 951 may not be screwed into the positioning member 710 at the positions that are lower in the direction of gravity than the above abutting portion.

In the gas laser device 100 of the present embodiment, the number of provided through-holes 851 is two, and the through-holes 851 are provided in parallel.

In this configuration, since the fixing members 951 penetrate through the through-holes 851 respectively, the two fixing members 951 are screwed into the positioning member 710. In this manner, the monitor module 160 may be less likely to be displaced in the internal space of the accommodating portion 110 than in a case where there is one through-hole 851. Note that the number of through-holes 851 may not be two and each of the through-holes 851 may not be provided in parallel.

In the gas laser device 100 of the present embodiment, the monitor module 160 includes the guide groove 855 that straddles the first guide member 730.

With this configuration, the guide groove 855 that straddles the first guide member 730 can facilitate the movement of the monitor module 160 in the Z direction and can suppress movement of the monitor module 160 in a direction other than the Z direction. Note that the guide groove 855 may not be provided.

Furthermore, in the gas laser device 100 of the present embodiment, the end of the guide groove 855 on the advancing side to the first guide member 730 is provided with the tapered portion 855a with a width in the H direction reduced toward the other end on the opposite side to the end.

The configuration can facilitate the insertion of the first guide member 730 into the guide groove 855 when the monitor module 160 advances toward the first guide member 730. Note that the tapered portion 855a may not be provided.

The gas laser device 100 of the present embodiment includes the second guide member 750 with which the monitor module 160 comes into contact in the H direction in the predetermined region A. Furthermore, the monitor module 160 comes into contact with the second guide member 750 in the predetermined region A and then slides along the second guide member 750 in the Z direction in a state where the monitor module 160 abuts on the second guide member 750.

With this the configuration, it is possible to prevent collision between the rear surface of the accommodating portion 110 and the monitor module 160 by bringing the monitor module 160 into contact with the second guide member 750. Furthermore, bringing the monitor module 160 into contact with the second guide member 750 and then sliding the monitor module 160 along the second guide member 750 can facilitate the movement of the monitor module 160 in the Z direction and can facilitate the abutting of the monitor module 160 on the positioning member 710. Note that the second guide member 750 may not be provided.

In the gas laser device 100 of the present embodiment, the second guide member 750 includes the cover portion 751 that covers the monitor module 160 in the V direction perpendicular to the optical plate 601 in the state where the monitor module 160 abuts on the second guide member 750.

With this the configuration, since the cover portion 751 covers the monitor module 160, the cover portion 751 can prevent the monitor module 160 from falling down. Note that although the cover portion 751 covers the abutting portion 161b of the base plate 161 in the present embodiment, it is only necessary for the cover portion 751 to cover any portion of the monitor module 160. Also, the cover portion 751 may not be provided.

Although the above embodiment has been described as examples, the present disclosure is not limited thereto, and various modifications can be made.

In the present embodiment, the monitor module 160 is positioned on the positioning member 710 by the first spherical pin 831, the second spherical pin 833, the V-shaped groove abutting portion 711, and the planar abutting portion 713. However, the configuration is not particularly limited as long as the monitor module 160 can be positioned on the positioning member 710.

The positioning member 710 of the present embodiment is disposed on the side further upstream than the monitor module 160. Incidentally, in a case where a part of the opening 115 closed by the newly installed module 631 is located on the side downstream the other part of the opening 115 that is not closed by the newly installed module 631, the monitor module 160 is pushed from the external space of the accommodating portion 110 into the internal space of the accommodating portion 110 through the other part of the opening 115. Then, the monitor module 160 slides downstream and is installed at a predetermined position behind the newly installed module 631. In this case, it is only necessary for the positioning member 710 to be disposed on the side further downstream than the monitor module 160. Also, it is only necessary for the fixing members 951 to be inserted into the through-holes 851 from the entrance region side.

In a top view of the through-holes 851, the through-holes 851 may not be provided in parallel on the respective sides of the guide groove 855.

Although both the first guide member 730 and the second guide member 750 are provided, it is only necessary for at least one of the first guide member 730 and the second guide member 750 to be provided. Although the upstream end of the first guide member 730 abuts on the positioning member 710, the upstream end may be located on the side further downstream than the positioning member 710 and may not abut on the positioning member 710, and the first guide member 730 may not guide the monitor module 160 to the positioning member 710. Although the upstream end of the second guide member 750 on the positioning member 710 side overlaps the positioning member 710 when the accommodating portion 110 is viewed from the opening 115, and the second guide member 750 guides the monitor module 160 to the positioning member 710, the present invention is not necessarily limited thereto. The upstream end may be located on the side further downstream than the positioning member 710, and the second guide member 750 may not guide the monitor module 160 to the positioning member 710. Furthermore, the upstream end may overlap the first guide member 730, and the second guide member 750 may guide the monitor module 160 only to the first guide member 730. Alternatively, the upstream end may be located on the side further downstream than the first guide member 730, and the second guide member 750 may not guide the monitor module 160 to the first guide member 730.

In the present embodiment, the second guide member 750 is not necessarily disposed on the main surface of the optical plate 601 and may be attached to the laser frame 111 on the rear surface of the accommodating portion 110.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Furthermore, it would be also obvious for those skilled in the art that embodiments of the present disclosure would be appropriately combined. The terms used throughout the present specification and the appended claims should be interpreted as “non-limiting” terms unless otherwise specifically indicated. For example, terms such as “comprise”, “include”, “have”, and “contain” should “not be interpreted to be exclusive of structural elements other than the described elements”. Furthermore, indefinite articles “a/an” should be interpreted to mean “at least one” or “one or more.” Furthermore, “at least one of A, B, and C” should be interpreted to mean any of A, B, C, A+B, A+C, B+C, and A+B+C as well as to include combinations of any thereof and any other than A, B, and C.

What is claimed is:

1. A gas laser device comprising:
an optical plate that is accommodated in an accommodating portion;
a monitor module that includes an entrance region through which light enters the monitor module, the monitor module being slidable on the optical plate;
a positioning member that is disposed on the optical plate and positions the monitor module at a predetermined position on the optical plate; and
a guide that extends in a direction parallel to an optical axis of the light traveling to the entrance region and guides the monitor module toward the positioning member in the direction parallel to the optical axis of the light,
the monitor module including a through-hole that penetrates through the monitor module in the direction parallel to the optical axis of the light and is provided at a position deviating from the entrance region, the monitor module sliding on the optical plate up to a predetermined region in a direction perpendicularly intersecting the optical axis of the light, then sliding along the guide in the direction parallel to the optical axis of the light toward the positioning member spaced apart from the predetermined region in the direction parallel to the optical axis of the light, and being fixed in an internal space of the accommodating portion through screwing of a fixing member that penetrates through the through-hole to the positioning member.

2. The gas laser device according to claim 1, wherein
the monitor module includes
a first spherical pin that is disposed on a surface that the positioning member faces, and
a second spherical pin that is disposed on the surface apart from the first spherical pin on the surface,
the positioning member includes
a V-shaped groove abutting portion that abuts on the first spherical pin at two points, a horizontal sectional shape of a part of the V-shaped groove abutting portion abutting on the first spherical pin being a V shape, and
a planar abutting portion, a horizontal sectional shape of a part of the planar abutting portion abutting on the second spherical pin being a planar shape, and
the monitor module is fixed in the internal space of the accommodating portion through the screwing of the fixing member to the positioning member in a state where the first spherical pin abuts on the V-shaped groove abutting portion and the second spherical pin abuts on the planar abutting portion.

3. The gas laser device according to claim 2, wherein
a line along which two surfaces constituting an inner surface of a V-shaped groove of the V-shaped groove abutting portion are in contact with each other is perpendicular to a main surface of the optical plate on which the monitor module slides, and an apex of the V-shaped groove is located on a surface including the optical axis of the light.

4. The gas laser device according to claim 2, wherein
the fixing member is screwed to the positioning member at a position lower in a direction of gravity than one of the V-shaped groove abutting portion and the planar abutting portion, the one being located at a lower position in the direction of gravity than the other thereof.

5. The gas laser device according to claim 2, wherein
the positioning member is disposed further upstream in a traveling direction of the light than the monitor module.

6. The gas laser device according to claim 5, wherein
the monitor module includes an exit region that is provided at a position deviating from the through-hole, the light that enters the monitor module from the entrance region exiting the exit region, and
the fixing member is inserted into the through-hole from a side of the exit region.

7. The gas laser device according to claim 1, wherein
a number of the through-holes is two, and the through-holes are provided in parallel.

8. The gas laser device according to claim 1, wherein
the positioning member is disposed further upstream in a traveling direction of the light than the monitor module.

9. The gas laser device according to claim 8, wherein
the monitor module includes an exit region that is provided at a position deviating from the through-hole, the light that enters the monitor module from the entrance region exiting the exit region, and
the fixing member is inserted into the through-hole from a side of the exit region.

10. The gas laser device according to claim 1, wherein
the guide includes a first guide member that is disposed in a region of the optical plate where the monitor module moves in the direction parallel to the optical axis of the light, and
the monitor module includes a guide groove that extends in the direction parallel to the optical axis of the light and straddles the first guide member.

11. The gas laser device according to claim 10, wherein
the first guide member guides the monitor module to the positioning member.

12. The gas laser device according to claim 10, wherein
an end of the guide groove on an advancing side to the first guide member is tapered such that a width in the direction perpendicularly intersecting the optical axis of the light decreases toward an end on an opposite side to the end.

13. The gas laser device according to claim 10, wherein
a number of the through-holes is two, and
the through-holes are provided in parallel on respective sides of the guide groove in a top view of the through-holes.

14. The gas laser device according to claim 10, wherein
the guide further includes a second guide member with which the monitor module comes into contact in the direction perpendicularly intersecting the optical axis of the light in the predetermined region, and
the monitor module comes into contact with the second guide member in the predetermined region and then slides along the second guide member in the direction parallel to the optical axis of the light in a state where the monitor module abuts on the second guide member.

15. The gas laser device according to claim 14, wherein
the second guide member guides the monitor module to the first guide member.

16. The gas laser device according to claim 14, wherein
the second guide member guides the monitor module to the positioning member.

17. The gas laser device according to claim 14, wherein
the second guide member includes a cover portion that covers the monitor module in a direction perpendicular to the optical plate in a state where the monitor module abuts on the second guide member.

18. The gas laser device according to claim 1, wherein
the guide includes a second guide member with which the monitor module comes into contact in the direction perpendicularly intersecting the optical axis of the light in the predetermined region, and
the monitor module comes into contact with the second guide member in the predetermined region and then slides along the second guide member in the direction parallel to the optical axis of the light in a state where the monitor module abuts on the second guide member.

19. The gas laser device according to claim 18, wherein
the second guide member guides the monitor module to the positioning member.

20. An electronic device manufacturing method comprising:
generating a laser beam with a gas laser device, the gas laser device including
an optical plate that is accommodated in an accommodating portion,
a monitor module that includes an entrance region through which light enters the monitor module, the monitor module being slidable on the optical plate,
a positioning member that is disposed on the optical plate and positions the monitor module at a predetermined position on the optical plate, and
a guide that extends in a direction parallel to an optical axis of the light traveling to the entrance region and guides the monitor module toward the positioning member in the direction parallel to the optical axis of the light,
the monitor module including a through-hole that penetrates through the monitor module in the direction parallel to the optical axis of the light and is provided at a position deviating from the entrance region, the monitor module sliding on the optical plate up to a predetermined region in a direction perpendicularly intersecting the optical axis of the light, then sliding along the guide in the direction parallel to the optical axis of the light toward the positioning member spaced apart from the predetermined region in the direction parallel to the optical axis of the light, and being fixed in an internal space of the accommodating portion through screwing of a fixing member that penetrates through the through-hole to the positioning member;
outputting the laser beam to an exposure device; and
exposing a photosensitive substrate to the laser beam within the exposure device to manufacture an electronic device.
